(19) United States
(12) Patent Application Publication
(10) Pub. No.: US 2012/0094421 A1
(43) Pub. Date: Apr. 19, 2012

(54) METHOD OF MANUFACTURING SOLAR CELL

(76) Inventors: Myung Su KIM, Yongin-si (KR); Dongseop Kim, Yongin-si (KR); Sungchan Park, Yongin-si (KR); Juhee Song, Yongin-si (KR)

(21) Appl. No.: 13/227,321

(22) Filed: Sep. 7, 2011

(30) Foreign Application Priority Data
Oct. 15, 2010 (KR) 10-2010-0101032

(51) Int. Cl. H01L 31/18

(52) U.S. Cl. 438/65; 257/E31.117

(57) ABSTRACT

In a method of manufacturing a solar cell, an emitter layer is formed on a front surface of a substrate, a rear surface protective layer is formed on the emitter layer, and a plurality of recesses is formed in the rear surface protective layer. Then, a front electrode is formed on the emitter layer, and a rear surface electrode layer is formed on the rear surface protective layer. A substrate is heated to form a rear surface electric field layer. Since a portion of the rear surface protective layer is removed when the recesses are formed, the substrate may be prevented from being damaged, and thus photoelectric conversion efficiency of the solar cell may be improved.

### CROSS-REFERENCE TO RELATED APPLICATION

This application relies for priority upon Korean Patent Application No. 10-2010-0101032 filed on Oct. 15, 2010, the contents of which are herein incorporated by reference in its entirety.

### BACKGROUND

1. Field of disclosure

The present invention relates to a method of manufacturing a solar cell. In particular, the present invention relates to a method of manufacturing a single crystalline silicon solar cell.

2. Description of the Related Art

In general, photoelectric devices are used to convert light energy into electrical energy. As one of the photoelectric devices, a photovoltaic solar cell converts solar energy into electrical energy. A solar cell may have either a PN structure, in which a p-type semiconductor layer is coupled with an n-type semiconductor layer; or a p-i-n structure, in which the p-type semiconductor layer, the n-type semiconductor, an intrinsic semiconductor layer disposed between the p-type semiconductor layer and the n-type semiconductor layer are coupled with each other. The semiconductor layers absorb solar energy and the photoelectric effect generates electrons and holes. When a bias is applied to the solar cell, the photovoltaic cell produces an electrical current generated by the electrons and the holes.

The photoelectric conversion efficiency of the solar cell is the ratio of the amount of the electrical current generated by the solar cell to the amount of light provided to the solar cell. The photoelectric conversion efficiency of the solar cell is an important metric for improving the solar cell since it is directly related to the capability of the solar cell to produce electrical energy.

### SUMMARY

Exemplary embodiments of the present invention provide a method of manufacturing a solar cell to improve its photoelectric conversion efficiency.

According to the exemplary embodiments, a method of manufacturing a solar cell is provided as follows. An emitter layer is formed on a front surface of a substrate, a rear surface protective layer is formed on the emitter layer, and a plurality of recesses is formed in the rear surface protective layer. A front surface electrode is formed on the emitter layer, and a rear surface electrode layer is formed on the rear surface protective layer. Then, the substrate is heated to form a rear surface electric field layer.

Particularly, a front surface of the substrate, which is doped with a first conductive type impurity, is doped with a second conductive type impurity to form the emitter layer. The substrate may be a silicon layer doped with a p-type impurity and the emitter layer may be a layer doped with an n-type impurity. Then, the rear surface protective layer is formed on a rear surface of the substrate.

Then, portions of the rear surface protective layer are removed to form a plurality of recesses. In order to prevent the rear surface of the substrate from being damaged, a portion of the rear surface protective layer remains in the recesses. A front surface electrode is formed on portions of the emitter layer. After the front surface electrode is formed, a metal layer is deposited on the rear surface protective layer to form the rear surface electrode layer.

The substrate on which the front surface electrode and the rear surface electrode layer are formed is heated to form the rear surface electric field layer in each of the recesses. Then, a material of the front surface electrode is diffused into the emitter layer such that the front surface electrode makes contact with the emitter layer.

According to the above, when the recesses are formed in portions of the rear surface protective layer, the rear surface protective layer partially remains in each of the recesses, thereby preventing the substrate from being damaged. Thus, a photoelectric conversion efficiency of the solar cell may be prevented from being lowered due to the damage of the substrate.

### BRIEF DESCRIPTION OF THE DRAWINGS

The above and other advantages of the present invention will become readily apparent by reference to the following detailed description when considered in conjunction with the accompanying drawings wherein:

FIG. 1 is a flowchart showing a method of manufacturing a solar cell according to a first exemplary embodiment of the present invention;

FIGS. 2A to 2J are cross-sectional views showing a method of manufacturing the solar cell according to the first exemplary embodiment of the present invention;

FIGS. 3A to 3E are cross-sectional views showing a method of manufacturing a solar cell according to a second exemplary embodiment of the present invention;

FIGS. 4A to 4E are cross-sectional views showing a method of manufacturing a solar cell according to a third exemplary embodiment of the present invention; and

FIGS. 5A to 5C are cross-sectional views showing a method of manufacturing a solar cell according to a fourth exemplary embodiment of the present invention.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

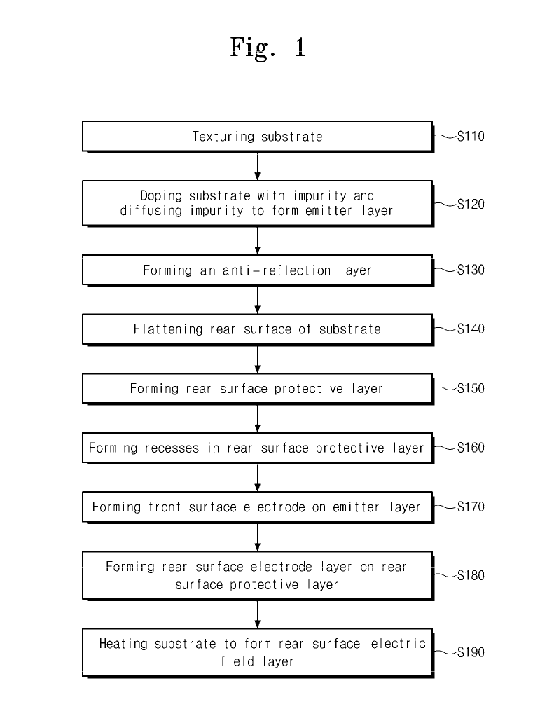

FIG. 1 is a flowchart showing a method of manufacturing a solar cell according to a first exemplary embodiment of the present invention.

This method to manufacture a solar cell begins with a substrate doped with a first type of conductive impurity. Referring to FIG. 1, this substrate is textured S110 by dipping into an etchant such as a sodium hydroxide solution to etch the substrate. Then the substrate is doped with a second type of conductive impurity, and the doped substrate is heated to diffuse the second impurity into the substrate, thereby forming an emitter layer on a whole surface of the substrate S120. After that an anti-reflection layer is formed on the emitter layer S130.

Because a rear surface of the substrate is etched along with the front surface of the substrate by the etchant during the texturing process S110, the etched rear surface of the substrate is flattened S140. Then a rear surface protective layer is formed on the flattened rear surface of the substrate S150. The rear surface protective layer may be formed in a single layer or a multi-layer.

Next, portions of the rear surface protective layer are removed to form a plurality of recesses S160. When forming the recesses as described above, a portion of the rear surface protective layer remains in each recess to reduce damage of the rear surface of the substrate. Detailed descriptions of the above will be described later.

After the recesses are formed, a front surface electrode is formed on the emitter layer S170. Then a rear surface electrode layer is formed on the rear surface protective layer S180. Next, when the substrate is heated, a metal material on the rear surface electrode layer is diffused into the rear surface of the substrate. As a result, a rear surface electric field layer is formed in an area into which the metal material is diffused S190.

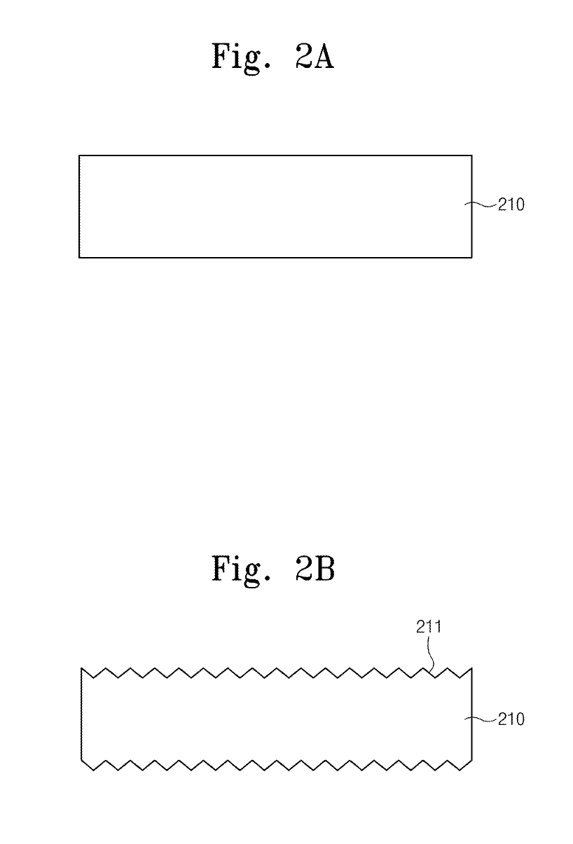

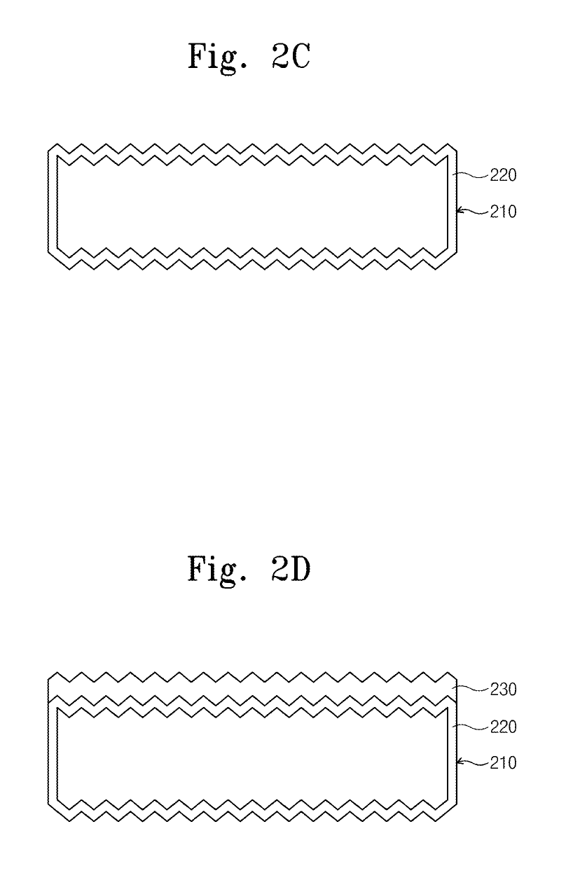

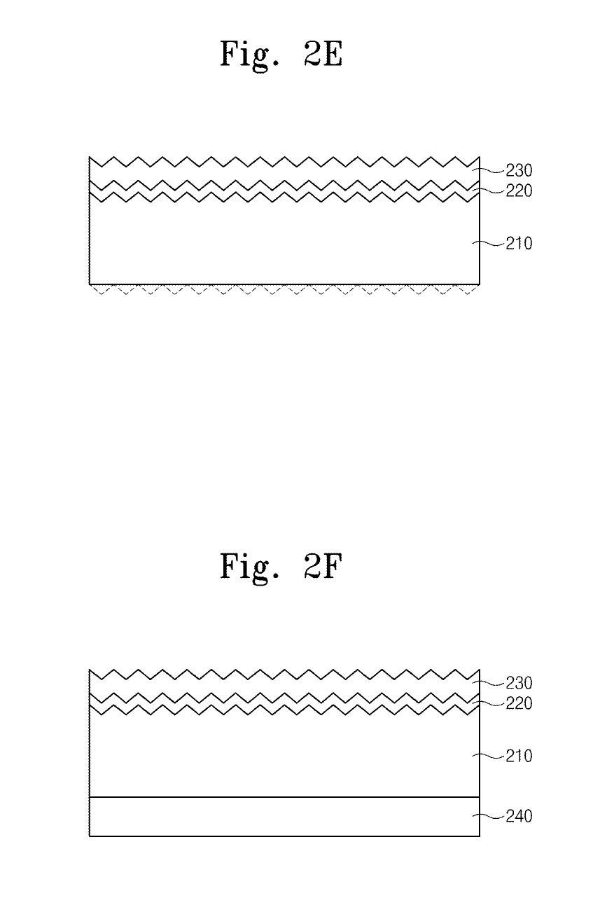

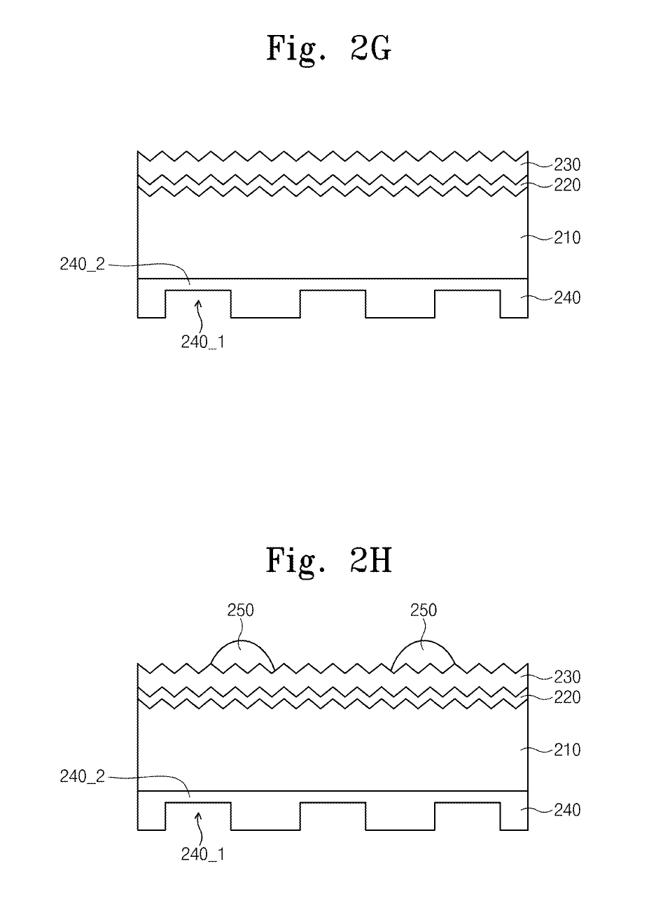

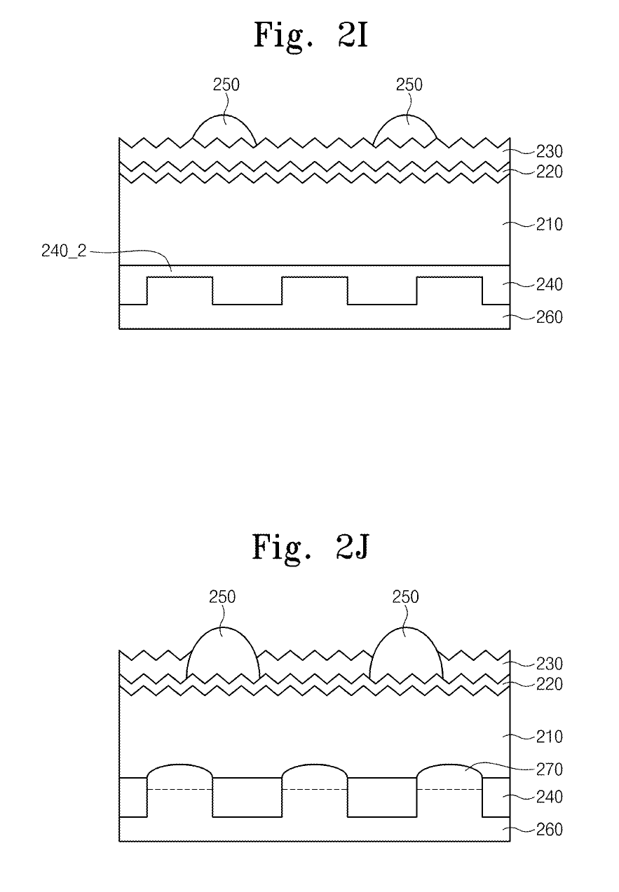

Hereinafter, a method of manufacturing a solar cell according to the present invention will be described in detail with reference to FIGS. 2A to 2J.

FIGS. 2A to 2J are cross-sectional views showing a method of manufacturing the solar cell according to the first exemplary embodiment of the present invention.

Referring to FIG. 2A, a substrate 210 is cleaned to remove damaged portions or foreign substances on the substrate 210. The substrate 210 is a substrate which is doped with an impurity. As an example, the substrate 210 may be a p-type single crystalline silicon wafer. In addition, both surfaces of the substrate 210 may be etched using an alkali solution or an acid solution, so that the damaged portions of the substrate 210 may be removed.

Referring to FIG. 2B, a front surface and a rear surface of the substrate 210 are textured to have a pyramid shape. The front and rear surfaces of the substrate 210 may be textured by using a wet etching process by using an etchant.

When the substrate 210 is etched, the substrate 210 is dipped into the etchant. Therefore, both of the front and rear surfaces of the substrate 210 may be textured as shown in FIG. 2B. In FIG. 2B, the textured pyramid shapes have the same size with each other, however, the size of the textured pyramid shapes should not be limited thereto. That is, protruding portions 211 protruded by the texturing process may have random sizes.

The protruding portions 211 in the pyramid shape cause a ray of sunlight traveling from the exterior into the substrate 210 to increase optical path of the light in the substrate 210. Thus, a ray of sunlight is more efficiently absorbed by substrate 210, and the conversion efficiency of the solar cell increases.

Referring to FIG. 2C, an emitter layer 220 is formed on a front surface of the substrate 210. The emitter layer 220 is doped with an impurity opposite to a type of an impurity in the substrate 210 to form a PN junction with the substrate 210. As an example, the emitter layer 220 may be a silicon layer doped with an n-type impurity.

The emitter layer 220 may be formed by a chemical vapor deposition (CVD) process using a phosphoryl chloride gas (POCl₃) at a high temperature. Particularly, when the substrate 210 is exposed to vapor including the phosphoryl chloride gas POCl₃, a phosphorus silicate glass (PSG, P₂O₅) layer (not shown) is formed on the substrate 210. Then, when the n-type impurity is diffused by heating the substrate 210, the n-type impurity is diffused to the substrate 210 to form the emitter layer 220. Thus, the emitter layer 220 is the silicon layer doped with the n-type impurity. After the emitter layer 220 is formed, the PSG layer is dipped into a hydrogen fluoride HF solution so as to be removed.

During the diffusion process, the n-type impurity may be diffused to not only the front surface of the substrate 210 but also the exposed portions of the substrate 210, for example, edges and the rear surface of the substrate 210. Thus, the portions doped with the n-type impurity except for the emitter layer 220 formed on the front surface of the substrate 210 are removed in the following process.

Referring to FIG. 2D, an anti-reflection layer 230 is formed on the emitter layer 220. The anti-reflection layer 230 may include silicon nitride (SiN) or titanium oxide (TiO₂) to decrease the reflectance of the substrate 210. In the present exemplary embodiment, the anti-reflection layer 230 may be formed by a chemical vapor deposition (CVD) process using silane gas and ammonia gas.

In the first exemplary embodiment, the anti-reflection layer 230 is a single layer, however it should not be limited thereto. That is, the anti-reflection layer 230 may include two or more layers.

Referring to FIG. 2E, the n-type doped region formed on the sides and the rear surface of the substrate 210 and the textured portion of the rear surface of the substrate 210 are removed. The n-type doped region of the edges of the substrate 210 may be removed by plasma etching obtained by ionizing fluorocarbon gas (CHF₃ or CF₄), or only the edges of the substrate 210 may be removed by using a laser beam after exposure to plasma. The textured region of the substrate 210 may be removed by using the etchant.

Referring to FIG. 2F, a rear surface protective layer 240 may be formed on the flattened rear surface of the substrate 210. Semiconductor theory predicts that addition of the rear surface protective layer 240 removes a dangling bond that involves the movement of the electrons or holes and prevents a leakage current.

The rear surface protective layer 240 may be formed by a chemical vapor deposition process, either in the absence or presence of a plasma. In CVD, the substrate 210 is put into a furnace in a high temperature condition, and then, a source gas is supplied to the furnace in the high temperature condition to deposit the rear surface protective layer 240. In the plasma-assisted CVD process, the source gas forms a low temperature plasma which deposits the rear surface protective layer 240 on the rear surface of the substrate 210. The rear surface protective layer 240 may be formed of one of aluminum oxide (AlO), silicon nitride (SiN), silicon oxide (SiO₂), or silicon cyanide (SiCN).

In the first exemplary embodiment, the rear surface protective layer 240 may be a single layer. The rear surface protective layer 240 is required to have a thickness which is adequate not to be damaged during subsequent processes, for example, a rear surface electrode layer forming process and a heating process. For instance, when the rear surface electrode layer is formed by a screen process, the thickness of the rear surface protective layer 240 may depend on a paste used in the screen process. As an example, the rear surface protective layer 240 may have a thickness of about 50 nm to about 200 nm.

Referring to FIG. 2G, portions of the rear surface protective layer 240 are removed to form a plurality of recesses 240_1. The recesses 240_1 are formed in an area where a rear surface electric field layer is formed by the following process.

The recesses 240_1 may be formed by a photolithography process and an etching process. In detail, a photoresist pattern is formed on the rear surface protective layer 240 using a positive photoresist such that the areas in which the recesses 240_1 are formed are exposed, and then the exposed areas are etched using the photoresist pattern as a mask, to thereby form the recesses 240_1. The etching process may be a wet-etching process using an etchant or a dry-etching process using a gas. Alternatively, the recesses 240_1 may be formed by using a laser beam. In particular, a laser beam irradiates the areas where the recesses 240_1 are formed on the rear surface protective layer 240 to form the recesses 240_1. The laser beam used to form the recesses 240_1 is a nano-second pulse width laser beam or a pico-second pulse width laser beam appropriately absorbed by the rear surface protective layer 240. When compared to a semiconductor process such as the etching process, the laser process may be more simplified.

During the process of forming the recesses 240_1, in the case that the rear surface protective layer 240 is removed to expose the rear surface of the substrate 210, the rear substrate of the substrate 210 may be damaged by the etchant or the laser beam. For example, when the rear surface protective layer 240 is removed by using the nano-second pulse width laser beam, the rear surface of the substrate 210 may be melted by the laser beam and then recrystallized. In addition, in the case that the rear surface protective layer 240 is removed by using the pico-second pulse width laser beam, the rear surface of the substrate 210 may be cracked. Thus, in order to prevent the substrate 210 from being damaged, the rear surface protective layer 240 is not completely removed from the areas where the recesses 240_1 are formed, so that a portion of the rear surface protective layer 240 remains in the recesses 240_1 to form a residual layer 240_2. The thickness of the residual layer 240_2 may be changed according to the thickness of the rear surface protective layer 240. As an example, in the case that the rear surface protective layer 240 has a thickness equal to or thicker than about 60 nm, the residual layer 240_2 may have a thickness of about 0.1 nm to about 50 nm.

Referring to FIG. 2H, a front surface electrode 250 is formed on portions of the emitter layer 220. The front surface electrode 250 may be formed of silver (Ag). That is, the front surface electrode 250 may be formed by screen printing a silver electrode paste.

Referring to FIG. 21, a rear surface electrode layer 260 is formed on the rear surface protective layer 240. The rear surface electrode layer 260 may include aluminum (Al). The rear surface electrode layer 260 is formed on an entire surface of the rear surface protective layer 240. The rear surface electrode layer 260 may be formed by screen printing an electrode paste as in the same manner as the front surface electrode 250.

Referring to FIG. 2J, the substrate 210 is heated such that a metal material of the front surface electrode 250 and a metal material of the rear surface electrode layer 260 are diffused into the substrate. Through the above process, the front surface electrode 250 penetrates through the anti-reflection layer 230 to make contact with the emitter layer 220. Also, the metal material of the rear surface electrode layer 260 diffuses into the rear surface of the substrate 210 to form a rear surface electric field layer 270. As an example, the metal material of the rear surface electrode layer 260 may be aluminum (Al). Since the aluminum (Al) is one of p-type impurities included in group-III elements and the substrate 210 is the p-type silicon substrate, the area into which the aluminum Al diffuses has a higher doping density than its surrounding area. The rear surface electric field layer 270 forms an electric field near the rear surface electrode layer 260, so that electrons generated near the rear surface may be prevented from recombining in the rear surface electrode layer 260.

When the rear surface electrode layer 260 diffuses into the substrate 210, the residual layer 240_2 is melted by the metal material of the rear surface electrode layer 260, so the rear surface electric field layer 270 may include components from the residual layer 240_2. However, since the residual layer 240_2 includes silicon, nitride, or aluminum, the rear surface electric field layer 270 may retain its n-type characteristics.

As described above in the first exemplary embodiment, a portion of the rear surface protective layer 240 remains in the recesses 240_1 when the recesses 240_1 are formed in the rear surface protective layer 240, so that the substrate 210 may be prevented from being damaged. Thus, the photoelectric conversion efficiency of the solar cell may be prevented from being lowered due to the damage of the substrate 210.

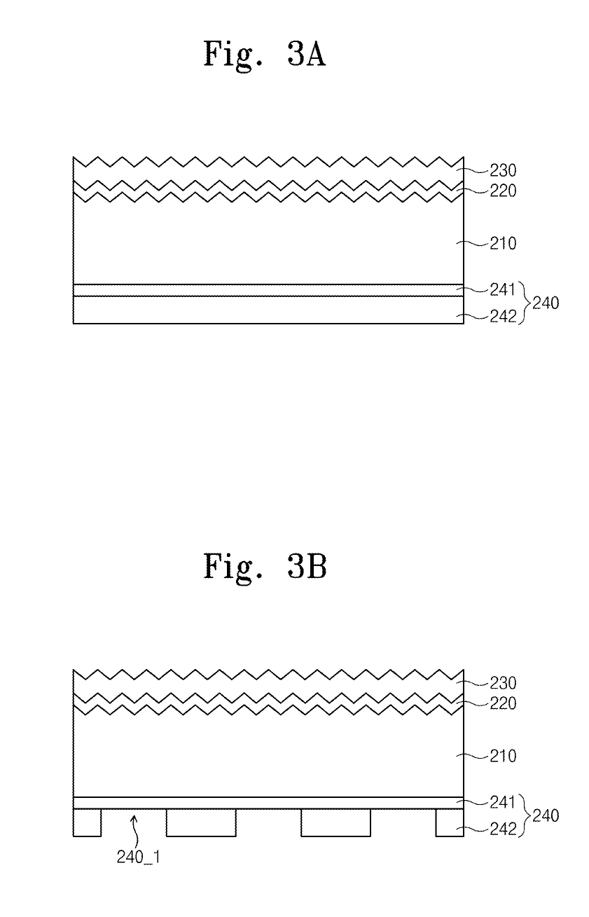

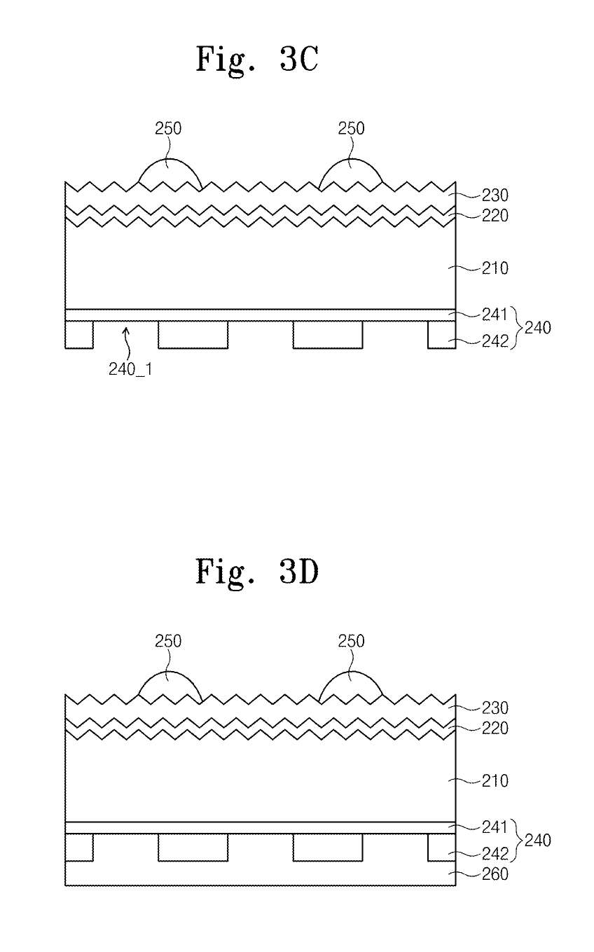

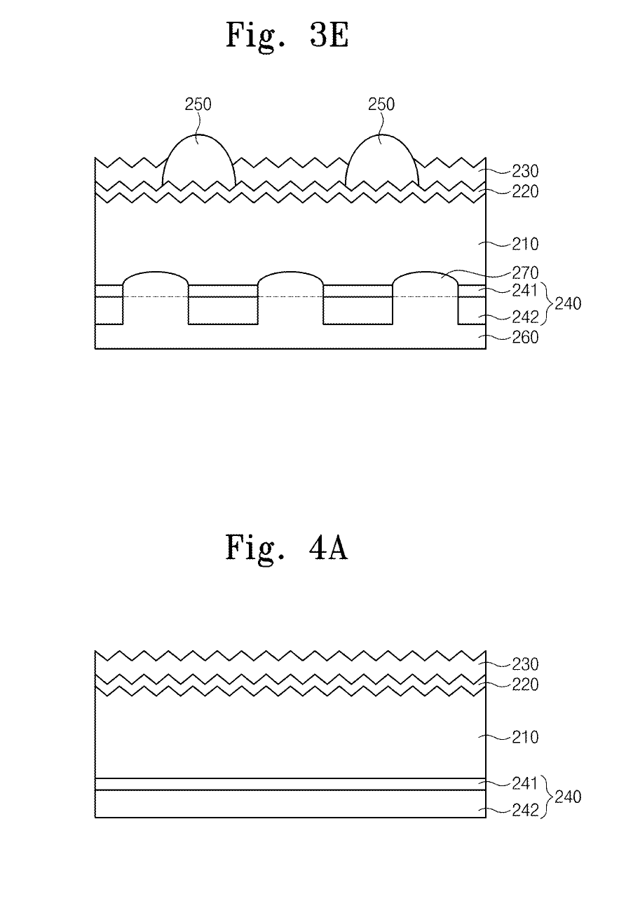

FIGS. 3A to 3E are cross-sectional views showing a method of manufacturing a solar cell according to a second exemplary embodiment of the present invention. In FIGS. 3A to 3E, the same reference numerals denote the same elements in FIGS. 2A to 2J, and thus the detailed descriptions of the same elements will be omitted.

In the second exemplary embodiment, manufacturing processes prior to FIG. 3A are the same as the manufacturing process shown in FIGS. 2A to 2C, and thus, detailed descriptions of the same will be omitted.

Referring to FIG. 3A, a rear surface protective layer 240 is formed on a flattened rear surface of a substrate 210. In the second exemplary embodiment, the rear surface protective layer 240 includes a first protective layer 241 and a second protective layer 242 formed on the first protective layer 241. The first protective layer 241 has a thickness thinner than the second protective layer 242. As an example, the first protective layer 241 may have a thickness of about 5 nm to about 50 nm. In the case that the first protective layer 241 has a thickness thinner than 5 nm, the first protective layer 241 may not serve the same function as a protective layer. The second protective layer 242 may have a thickness of about 100 nm to about 5000 nm.

The first protective layer 241 may include a material different from the second protective layer 242. As an example, the first protective layer 241 may include aluminum oxide or silicon oxide, and the second protective layer 242 may include silicon cyanide or silicon nitride.

Similarly to the process described in the first exemplary embodiment, the first and second protective layers 241 and 242 may be formed by a chemical vapor deposition (CVD) process, either plasma-assisted or not.

Referring to FIG. 3B, portions of the rear surface protective layer 240 are removed to form a plurality of recesses 240_1. The recesses 240_1 are formed in an area where a rear surface electric field layer is formed by the following process. The recesses 240_1 may be formed by a photolithography process, an etching process, or a laser beam as described in the first exemplary embodiment.

As described in the first exemplary embodiment, when the rear surface protective layer 240 is removed to expose the rear surface of the substrate 210, the rear surface of the substrate 210 may be damaged by the etchant or the laser beam. Thus, in order to prevent the substrate 210 from being damaged, the second protective layer 242 is removed in the areas where the recesses 240_1 are formed, and the first protective layer 241 is retained in the areas in which the second protective layer 242 is removed.

Referring to FIG. 3C, a front surface electrode 250 is formed on portions of an emitter layer 220. The process of forming the front surface electrode 250 is the same as the process in the first exemplary embodiment, detailed descriptions of the forming of the front surface electrode 250 will be omitted.

Referring to FIG. 3D, a rear surface electrode layer 260 is formed on the second protective layer 242. The rear surface electrode layer 260 may be formed of a material having aluminum (Al) as a main component. The rear surface electrode layer 260 is formed on an entire surface of the second protective layer 242. The rear surface electrode layer 260 may be formed by screen printing an electrode paste.

Referring to FIG. 3E, the substrate 210 is heated such that a metal material of the front surface electrode 250 and a metal material of the rear surface electrode layer 260 are diffused into the substrate 210. During the heating process, the front surface electrode 250 is penetrated into the anti-reflection layer 230 to make contact with the emitter layer 220. Also, the metal material of the rear surface electrode layer 260 is diffused into the rear surface of the substrate 210 to form a rear surface electric field layer 270.

When the rear surface electrode layer 260 is diffused into the substrate 210, the first protective layer 241 remaining in the recesses 240_1 is melted by the metal material of the rear surface electrode layer 260, so that the rear surface electric field layer 270 may include the component from the first protective layer 241. However, since the first protective layer 241 includes silicon, nitride, or aluminum, the rear surface electric field layer 270 may perform the same function as it previously has.

As described in the first exemplary embodiment, since the second protective layer 242 is removed in the areas where the recesses 240_1 are formed, and the first protective layer 241 is retained in the areas in which the recesses 240_1 are formed, the substrate 210 may be prevented from being damaged. Thus, the photoelectric conversion efficiency of the solar cell may be prevented from being lowered due to the damage of the substrate 210.

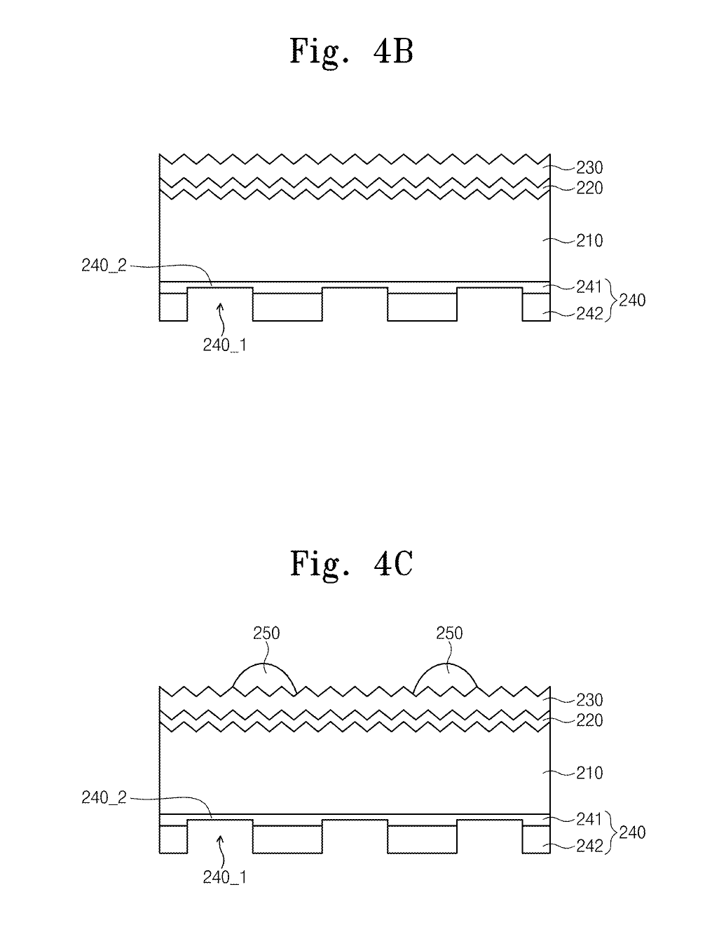

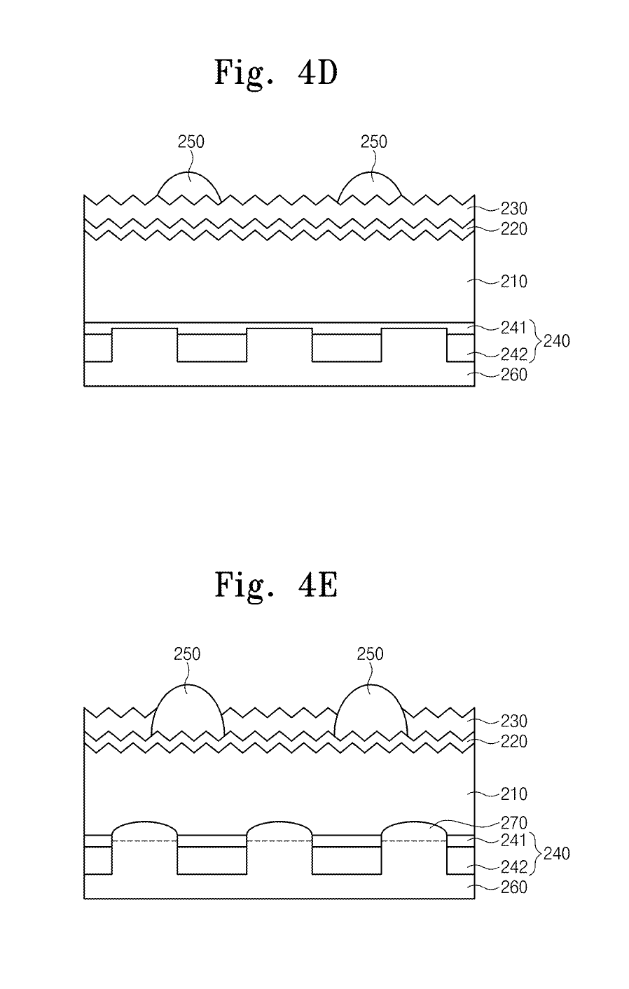

FIGS. 4A to 4E are cross-sectional views showing a method of manufacturing a solar cell according to a third exemplary embodiment of the present invention. In the third exemplary embodiment, since manufacturing processes prior to FIG. 4A are the same as the manufacturing processes shown in FIGS. 2A to 2C, detailed descriptions of the same elements will be omitted. In addition, in FIGS. 4A to 4E, the same reference numerals denote the same elements in FIGS. 2A to 2J and in FIGS. 3A to 3E, and thus the detailed descriptions of the same elements will be omitted.

Referring to FIG. 4A, a rear surface protective layer 240 is formed on a flattened rear surface of a substrate 210. In the third exemplary embodiment, the rear surface protective layer 240 includes a first protective layer 241 and a second protective layer 242 formed on the first protective layer 241. The first protective layer 241 is thinner than the second protective layer 242. As an example, the first protective layer 241 may have a thickness of about 5 nm to about 200 nm. In the case that the first protective layer 241 is thinner than 5 nm, the first protective layer 241 may not serve the same function as a protective layer. In addition, because it takes a long time to form the first protective layer 241, the first protective layer 241 does not need to have a thickness equal to or thicker than 200 nm. The second protective layer 242 may have a thickness of about 10 nm to about 5000 nm.

The first protective layer 241 may include a material different from the second protective layer 242. As an example, the first protective layer 241 may include aluminum oxide or silicon oxide, and the second protective layer 242 may include silicon cyanide or silicon nitride.

As described in the first exemplary embodiment, the first and second protective layers 241 and 242 may be formed by a chemical vapor deposition (CVD) process, with or without plasma assistance.

Referring to FIG. 4B, portions of the rear surface protective layer 240 are removed to form a plurality of recesses 240_1. The recesses 240_1 are formed in areas where a rear surface electric field layer is formed by the following process. The recesses 240_1 may be formed by a photolithography process, an etching process, or a laser beam as described in the first exemplary embodiment.

As described in the first exemplary embodiment, when the rear surface protective layer 240 is removed to expose the rear surface of the substrate 210, the rear surface of the substrate 210 may be damaged by the etchant or the laser beam. Thus, in order to prevent the substrate 210 from being damaged, the second protective layer 242 is removed in the areas where the recesses 240_1 are formed, and the first protective layer 241 is retained in the areas where the second protective layer 242 is removed to form a residual layer 240_2. In the second exemplary embodiment, all the first protective layer 241 is retained in the areas where the second protective layer 242 is removed. In the third exemplary embodiment, however, only a portion of the first protective layer 241 is retained to form the residual layer 240_2. As an example, the residual layer 240_2 may have a thickness of about 0.1 nm to about 50 nm. In detail, when the first protective layer 241 has the thickness of about 5 nm, the residual layer 240_2 may have a thickness of about 0.1 nm to about 5 nm. In the case that the first protective layer 241 has a thickness of about 10 nm, the residual layer 240_2 may have a thickness of about 0.1 nm to about 10 nm. In addition, in the case that the first protective layer 241 has a thickness of about 60 nm, the residual layer 240_2 may have a thickness of about 0.1 nm to about 50 nm.

Referring to FIG. 4C, a front surface electrode 250 is formed on portions of an emitter layer 220. The process of forming the front surface electrode 250 is the same as the process shown in the first exemplary embodiment, and thus detailed descriptions of forming the front surface electrode 250 will be omitted.

Referring to FIG. 4D, a rear surface electrode layer 260 is formed on the second protective layer 242. The process of forming the rear surface electrode layer 260 is the same as the process shown in FIG. 3D, so that detailed description of the forming of the rear surface electrode layer 260 will be omitted.

Referring to FIG. 4E, the substrate 210 is heated to effect penetration of a metal material of the front surface electrode 250, and of a metal material of the rear surface electrode layer 260 into the substrate 210. Since the process shown in FIG. 4E is similar to the process shown in FIG. 3E, detailed description of the above will be omitted.

When the rear surface electrode layer 260 is diffused into the substrate 210, since the residual layer 240_2 is melted by the metal material of the rear surface electrode layer 260, the rear surface electric field layer 270 may include the component from the residual film 240_2. However, since the residual film 240_2 includes silicon, nitride, or aluminum, the rear surface electric field layer 270 may perform the same function as it previously has.

In the third exemplary embodiment, since all the second protective layer 242 is removed in the areas where the recesses 240_1 are formed and a portion of the first protective layer 241 remains in the areas where the second protective layer 242 is removed, the substrate 210 may be prevented from being damaged. Thus, the photoelectric conversion efficiency of the solar cell may be prevented from being lowered due to the damage of the substrate 210.

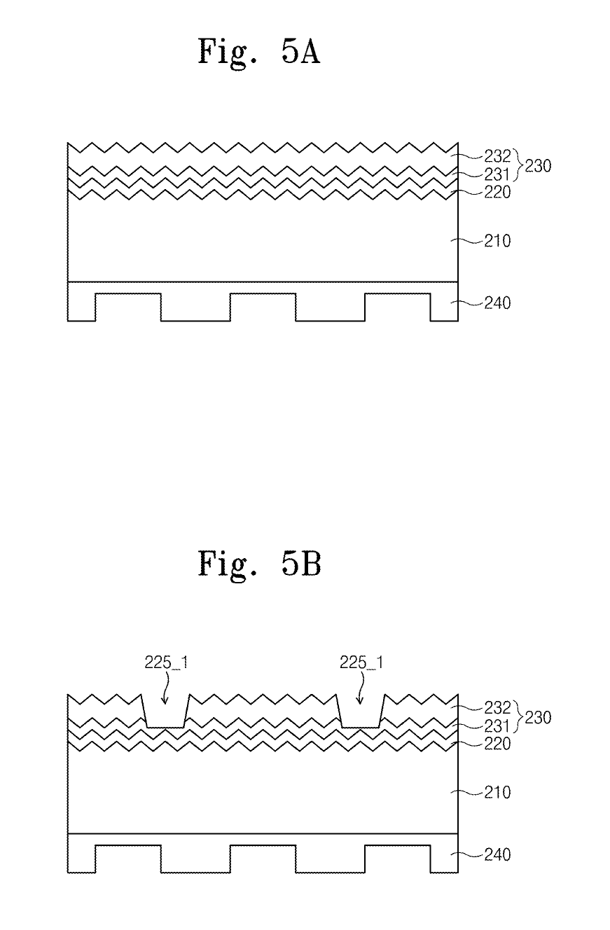

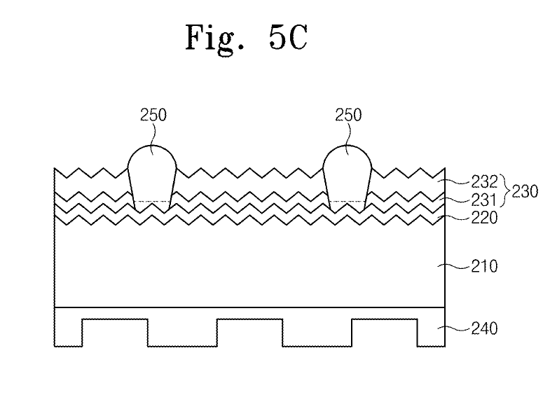

FIGS. 5A to 5C are cross-sectional views showing a method of manufacturing a solar cell according to a fourth exemplary embodiment of the present invention. In the fourth exemplary embodiment, since manufacturing processes prior to FIG. 5A are the same as the manufacturing processes of the FIGS. 2A to 2E, detailed descriptions of the same elements will be omitted. In addition, in FIGS. 5A to 5C, the same reference numerals denote the same elements in FIGS. 2A to 2J, and thus the detailed descriptions of the same elements will be omitted.

Referring to FIG. 5A, an anti-reflection layer 230 includes a first anti-reflection layer 231 and a second anti-reflection layer 232, which are sequentially formed on the emitter layer 220. The first and second anti-reflection layer s 231 and 232 are formed through the same process as the process shown in FIG. 2D. In the present exemplary embodiment, the first anti-reflection layer 231 may include silicon oxide, and the second anti-reflection layer 232 may include silicon nitride.

Referring to FIG. 5B, recesses 225_1 are formed in portions of the anti-reflection layer 230. In the following process, a front electrode makes contact with the emitter layer 220 in the areas where the recesses 225_1 are formed. The recesses 225_1 may be formed by a laser beam, a wet etching process, or a dry etching process similar to the descriptions in previous embodiments of processes for forming the recesses 240_1 in the rear surface protective layer 240.

When the rear surface protective layer 240 is removed to expose the emitter layer 220, the emitter layer 220 may be damaged by the etchant or the laser beam. Thus, in order to prevent the substrate 210 from being damaged, the second anti-reflection layer 232 is removed in the areas where the recesses 225_1 are formed, and the first anti-reflection layer 231 is retained in the areas where the second anti-reflection layer 232 is removed to form a residual layer.

Referring to FIG. 5C, the front surface electrode 250 is formed in each of the recesses 225_1. The method of forming the front surface electrode 250 may be the same as the method shown in FIG. 2H.

In the fourth exemplary embodiment, manufacturing processes following the process shown in FIG. 5C may be the same as the manufacturing processes shown in FIGS. 21 to 2J, so detailed descriptions of the same will be omitted.

According to the above, in the fourth exemplary embodiment, the anti-reflection layer 230 is partially removed in the areas where the front electrode 250 is formed. Therefore, the penetration of the metal material in the front surface electrode 250 may be deeper, and thus the contact between the emitter layer 220 and the front surface electrode 250 becomes higher. As a result, the specific conductivity at the interface between the front surface electrode 250 and the emitter layer 220 may be increased.

Also, during the process of forming the recesses 225_1, all the second anti-reflection layer 232 is removed in the areas where the recesses 225_1 are formed, and the first anti-reflection layer 231 is partially removed in the areas where the second anti-reflection layer 232 is removed such that a portion the first anti-reflection layer 231 remains. Accordingly, damage to the emitter layer 220 may be prevented.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method of manufacturing a solar cell, comprising:
doping a front surface of a substrate with a first conductive type impurity to form an emitter layer, the substrate being doped with a second conductive type impurity;
forming a rear surface protective layer on a rear surface of the substrate;
removing portions of the rear surface protective layer to form a plurality of recesses such that a portion of the rear surface protective layer is retained in the recesses;
forming a front surface electrode on portions of the emitter layer;
forming a rear surface electrode layer on the rear surface protective layer; and
heating the substrate to form a rear surface electric field layer in the recesses.

2. The method of claim 1, wherein the rear surface protective layer comprises at least two layers.

3. The method of claim 2, wherein the forming of the rear surface protective layer comprises:
forming a first protective layer on the rear surface of the substrate; and
forming a second protective layer on the first protective layer.

4. The method of claim 3 wherein the forming of the recesses comprises removing portions of the second protective layer to expose the first protective layer such that the first protective layer arranged in an area where the second protective layer is removed remains.

5. The method of claim 3, wherein the forming of the recesses comprises removing portions of the second protective layer and the first protective layer such that at least a portion of the first protective layer remains in the recesses.

6. The method of claim 3, wherein each of the first and second protective layers comprises aluminum oxide, silicon nitride, silicon oxide, or silicon cyanide.

7. The method of claim 1, wherein the recesses are formed by using a laser beam, a wet etching process, or a dry etching process.

8. The method of claim 1, further comprising forming an anti-reflection layer on the emitter layer prior to forming the rear surface protective layer.

9. The method of claim 8, wherein forming the front surface electrode further comprises removing portions of the anti-reflection layer, wherein the front surface electrode is formed in the portions from which the anti-reflection layer is removed.

10. The method of claim 9, wherein the anti-reflection layer is partially retained in the portions from which the anti-reflection layer is removed.

11. The method of claim 8, wherein the anti-reflection layer comprises:
a first anti-reflection layer formed on the emitter layer; and
a second anti-reflection layer formed on the first anti-reflection layer.

12. The method of claim 11, wherein the forming of the front surface electrode comprises removing portions of the first anti-reflection layer such that the portion of the second anti-reflection layer is retained in the portions from which the first anti-reflection layer is removed.

13. The method of claim 8, wherein the portions of the anti-reflection layer are removed by using a laser beam.

14. The method of claim 8, wherein the anti-reflection layer comprises at least one of silicon nitride or silicon oxide.

15. The method of claim 1, further comprising texturing the substrate prior to forming the emitter layer.

16. The method of claim 15, further comprising flattening the rear surface of the substrate prior to forming the rear surface protective layer.

17. The method of claim 1, wherein the substrate is a silicon substrate doped with a p-type impurity, and the emitter layer is a silicon layer doped with an n-type impurity

18. The method of claim 1, wherein the rear surface protective layer retained in the recesses has a thickness of about 0.1 nm to about 50 nm.
